(19) United States
(12) Patent Application Publication
(10) Pub. No.: US 2009/0039533 A1
(43) Pub. Date: Feb. 12, 2009

(54) ADHESION STRUCTURE FOR A PACKAGE APPARATUS

(75) Inventors: Hung-Tsun Lin, Taiwan (TW); Yu-Ren Chen, Tainan (TW)

Correspondence Address: SCHNECK & SCHNECK, P.O. BOX 2-E, SAN JOSE, CA, 95109-0005, US

(73) Assignee: CHIPMOS TECHNOLOGIES (BERMUDA) INC., Hamilton (BM)

(21) Appl. No.: 12/173,920

(22) Filed: Jul. 16, 2008

(30) Foreign Application Priority Data
Aug. 7, 2007 (TW) 096128942

(51) Int. Cl. H01L 23/12; H01L 21/58

(52) U.S. Cl. 257/783; 438/118; 257/E21.505; 257/E23.003

(57) ABSTRACT

A packaging apparatus is disclosed having a substrate with an interior area and a peripheral area. The substrate is configured to have an integrated circuit chip bonded to an adhesion structure located substantially within the interior area of the substrate. The substrate is further configured to have the integrated circuit chip electrically coupled to either the interior area on a distal surface of the substrate or the peripheral area on a proximate side of the substrate through a conductive structure. The adhesion structure includes a bonding area configured to accept an adhesive layer formed between the integrated circuit chip and the interior area of the substrate, and at least one protrusion structure being formed substantially within the bonding area of the substrate and configured to define a gap between the integrated circuit chip and the interior area of the substrate.

### TECHNICAL FIELD

The present invention relates generally to the field of semiconductor processing. More particularly, the present invention relates to an adhesion structure for a packaging apparatus for an integrated circuit chip that provides a uniform and substantial gap between a substrate and the chip.

### CROSS-REFERENCES TO RELATED APPLICATIONS

This application claims priority to Taiwan Patent Application No. 096128942, filed Aug. 7, 2007, the contents of which are hereby incorporated by reference in their entirety.

### BACKGROUND

Advanced semiconductor packaging technologies such as mini-ball-grid arrays (BGAs) and fine pitch BGAs (FBGAs) are becoming increasingly popular. These packaging technologies serve to bond a semiconductor integrated circuit chip to a substrate (known as a leadframe) via an adhesive layer. As the packaging technologies have become increasingly thin, chips are also becoming commensurately thinner. In the packaging process of such a thin package, the chip may sometimes be pressed too firmly against the adhesive layer while being bonded to the substrate, causing the liquid material of the adhesive layer to be squeezed beyond the chip sidewalls and adhere onto an unexpected region, e.g., the opposite surface of the chip not in contact with the adhesive layer. This is a so-called “adhesive creep” phenomenon.

Because the surface of the chip that is not in contact with the adhesive layer may have a conductive structure formed thereon to electrically connect with the substrate or external elements, the adhesive creep may disrupt such electrical connections leading to undesired consequences such as short-circuiting or an impedance disturbance. Therefore, unless a nonconductive adhesive is used for the adhesive layer, the packaging process may suffer from a serious defect arising from such a phenomenon. A further description of this phenomenon is made below.

With reference to FIG. 1, a prior art package apparatus 1 includes a substrate 11, a chip 12, an adhesive layer 13, and a conductive structure 14 (i.e., lead wires). Here, the adhesive layer 13 is connected to the conductive structure 14 due to the adhesive creep phenomenon. Consequently, when the adhesive layer 13 is made of a conductive adhesive, such an adhesive creep phenomenon will disrupt the electrical connection of the conductive structure 14, leading to undesired consequences such as short-circuiting and an impedance disturbance.

In an attempt to solve this problem, nonconductive adhesives have been used for the adhesive layer 13 in some prior art technologies. However, since nonconductive adhesives have a poorer heat dissipation performance compared to conductive adhesives, overheating tends to occur during the operation of the package apparatus which employs nonconductive adhesives.

In view of this, it is important to provide an adhesion structure for a package apparatus which both prevents the adhesive from creeping and adequately dissipates heat.

### SUMMARY

In an exemplary embodiment, a packaging apparatus is disclosed. The packaging apparatus includes a substrate having an interior area and a peripheral area. The substrate is configured to have an integrated circuit chip bonded to an adhesion structure located substantially within the interior area of the substrate. The substrate is further configured to have the integrated circuit chip electrically coupled to the peripheral area of the substrate through a conductive structure. The adhesion structure includes a bonding area configured to accept an adhesive layer formed between the integrated circuit chip and the interior area of the substrate, and at least one protrusion structure being formed substantially within the bonding area of the substrate and configured to define a gap between the integrated circuit chip and the interior area of the substrate.

In another exemplary embodiment, a packaging apparatus is disclosed. The packaging apparatus includes a substrate having an interior area and a peripheral area. The interior area surrounds a punched area located substantially within a central portion of the substrate. The substrate is configured to have an integrated circuit chip bonded to an adhesion structure located substantially within the interior area on a first surface of the substrate. The substrate is further configured to have the integrated circuit chip be electrically coupled to the interior area located on a second surface of the substrate through a conductive structure. The adhesion structure includes a bonding area configured to accept an adhesive layer formed between the integrated circuit chip and the interior area of the substrate, and at least one protrusion structure being formed substantially within the bonding area of the substrate and configured to define a gap between the integrated circuit chip and the interior area of the substrate.

In another exemplary embodiment, a method of mounting an integrated circuit chip in a packaging apparatus is disclosed. The method includes forming one or more adhesion structures onto an interior area on a first surface of a substrate where the one or more adhesion structures has a plurality of knobs, placing an adhesive material substantially within the interior area of the substrate and in proximity to the plurality of knobs, and adhering the integrated circuit chip to the substrate by placing the integrated circuit chip over the plurality of knobs and in contact with the adhesive material.

### BRIEF DESCRIPTION OF THE DRAWINGS

The appended drawings merely illustrate exemplary embodiments of the present invention and must not be considered as limiting its scope.

FIG. 1 is prior art packaging apparatus.

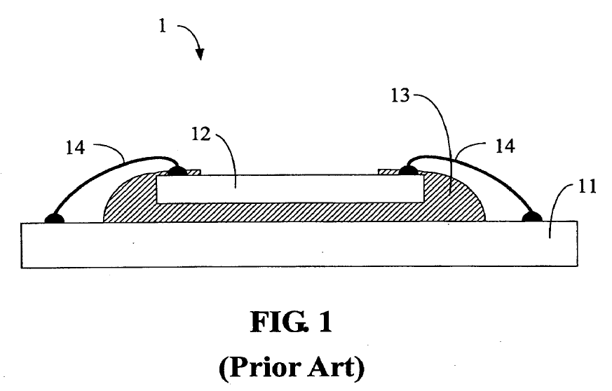

FIG. 2 illustrates an exemplary embodiment of a package apparatus in accordance with various embodiments of the present invention.

FIG. 3a illustrates another exemplary embodiment of a package apparatus in accordance with various embodiments of the present invention.

FIG. 3b illustrates a top view of a substrate of the exemplary package apparatus of FIG. 3a.

FIG. 4 illustrates another exemplary embodiment of the present invention having a protrusion structure located in an adhesion structure.

### DETAILED DESCRIPTION

In various exemplary embodiments described herein, an adhesion structure for a package apparatus comprising a chip and a substrate is disclosed. Generally, the adhesion structure comprises an adhesive layer and a protrusion structure. By use of the protrusion structure, a substantial gap is defined between the chip and the substrate.

To this end, a protrusion structure for such an adhesive layer is disclosed in the present invention. By forming a plurality of knobs at a certain height on the substrate, the chip will make contact with the top of the plurality of knobs when being bonded to the substrate, thus, leaving a substantial gap defined between the chip and the substrate.

Another exemplary embodiment of the present invention provides an adhesion structure for a package apparatus comprising a chip and a substrate. The substrate comprises a punched area where the adhesion structure is not formed. The adhesion structure comprises an adhesive layer and a protrusion structure. By use of this protrusion structure, a substantial gap is defined between the chip and the substrate.

To this end, a protrusion structure for such an adhesive layer is disclosed in the present invention. By forming a plurality of knobs at a certain height on the substrate except for the punched area, the chip will substantially make contact with the top of the plurality of knobs when being bonded to the substrate, thus leaving a substantial gap defined between the chip and the substrate.

The detailed technology and exemplary embodiments implemented for the present invention are described in the following paragraphs accompanying the appended drawings for people skilled in this field to well appreciate the features of the present invention.

Thus, various embodiments of the present invention relate to an adhesion structure that provides adequate adhesion. The embodiments are described below to explain this invention. However, these embodiments are not intended to limit the application or methods of the present invention in any specific context. Therefore, descriptions of the embodiments are only intended to illustrate rather than to limit the present invention. It should be noted that, in the following embodiments and attached drawings, elements not directly related to this invention are omitted from depiction, and the dimensional relationships depicted among various elements are only for purposes of illustration, rather than limiting the practical implementation of these elements.

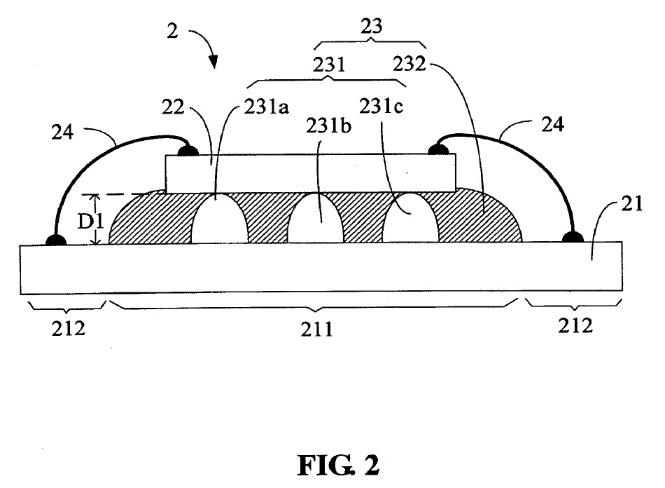

Referring now to FIG. 2, a package apparatus 2 includes an exemplary embodiment of an adhesion structure 23. The package apparatus 2 includes a substrate 21 and a chip 22. The substrate 21 has a first area 211 and a second area 212. The chip 22 is bonded to the first area 211 of the substrate 21 via the adhesion structure 23, and is electrically connected with the second area 212 of the substrate 21 via a plurality of conductive structures 24 (e.g., lead wires). The package apparatus 2 is suitable for products manufactured with, for example, a mini-BGA process.

The adhesion structure 23 includes a protrusion structure 231 and an adhesive layer 232. In this embodiment, the protrusion structure 231 includes a plurality of knobs 231a, 231b, 231c formed on the first area 211 of the substrate 21. Only knobs 231a, 231b, and 231c are shown here for purpose of simplicity. A skilled artisan will recognize that any number of knobs, laid out in various patterns, may be employed. For example, from a plan view perspective (not shown) the protrusion structure 231 may be either a one-dimensional array of rows of knobs or a two-dimensional array of knobs laid out on a Cartesian grid, radial pattern, or some other array pattern.

The protrusion structure 231 is formed in the adhesive layer 232 on the substrate 21 to define a substantial gap D1 between the chip 22 and the first area 211 of the substrate 21. The adhesive layer 232 is formed between the chip 22 and the first area 211 of the substrate 21 to bond the chip 22 to the substrate 21. With the protrusion structure 231, the chip 22 will slightly make contact with the top surface of the protrusion structure 231 when being bonded to the substrate 21, so that a substantial gap D1 is defined between the chip 22 and the substrate 21. In order for the gap D1 to separate the chip 22 from the substrate 21 appropriately, the protrusion structure has an average height above the substrate 21 ranging from about, for example, 10 to 75 micrometers (μm).

The adhesive layer 232 is formed only in the first area 211 corresponding to the chip 22, but not in the second area 212. Keeping the adhesive layer 232 from the second area 212 prevents a potential shorting of the conductive structures 24.

By forming the protrusion structure 231, a fixed gap may be maintained between the chip 22 and the substrate 21 after the two elements are bonded together. The creeping phenomenon of the adhesive into the other areas is thereby prevented because there is substantial space between the chip 22 and the substrate 21.

In this embodiment, the protrusion structure 231 may be formed from, for example, a metallic material to promote heat dissipation in the adhesion structure 23 while providing a gap D1 between the chip 22 and the substrate 21. Alternatively, the protrusion structure 231 may also be made from non-metallic materials in other embodiments. The adhesive layer 232 is made of a material selected from a group consisting of, for example, a conductive glue, a nonconductive glue, or a combination thereof. The materials enable the chip 22 to bind to the substrate 21. Since the protrusion structure 231 is formed to overcome the adhesive from creeping, a conductive glue may be used as the material of the adhesive layer 232 in a case of a thin chip.

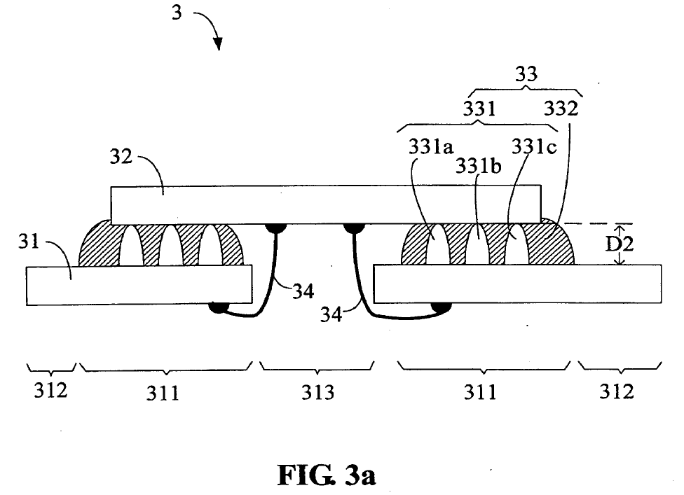

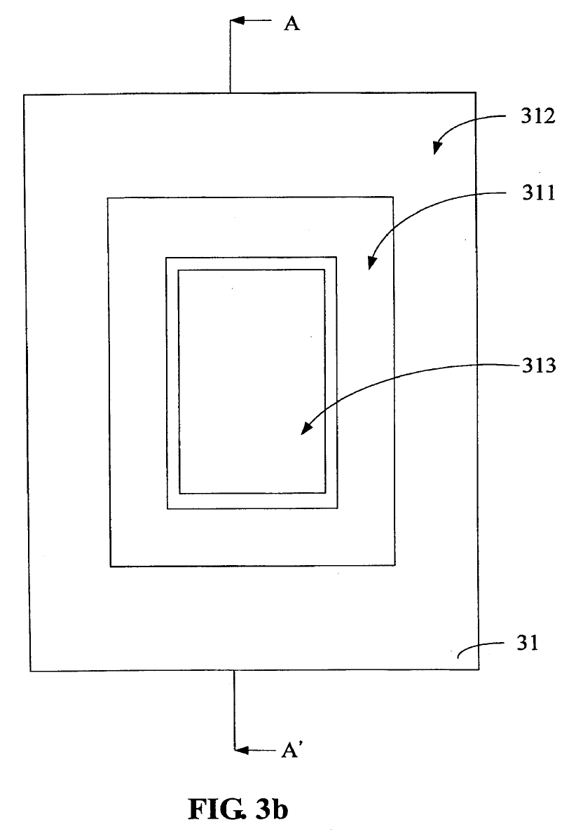

With reference to FIG. 3a, an exemplary embodiment of a package apparatus 3 includes an adhesion structure 33, a substrate 31, and a chip 32. The adhesion structure 33 includes a protrusion structure 331 and an adhesive layer 332. The protrusion structure 331 includes a plurality of knobs 331a, 331b, 331c.

Only knobs 331a, 331b and 331c are shown here for purpose of simplicity. A skilled artisan will recognize that any number of knobs, laid out in various patterns, may be employed. For example, from a plan view perspective (not shown) the protrusion structure 331 may be either a one-dimensional array of rows of knobs or a two-dimensional array of knobs laid out on a Cartesian grid, radial pattern, or some other array pattern.

The embodiment of FIG. 3a differs from the previous embodiment in that the substrate 31 further has a punched area 313 in addition to a first area 311 and a second area 312. A top view of the substrate 31 of the package apparatus 3 is depicted in FIG. 3b, where the substrate 31 in FIG. 3a represents a cross-section of the substrate 31 taken along a line AA′ in FIG. 3b. In this embodiment, the punched area 313 is disposed within the first area 311.

The chip 32 is bonded to the first area 311 of the substrate 31 via the adhesion structure 33, and is electrically connected with the first area 311 of the substrate 31 via a conductive structure 34 (e.g., a plurality of lead wires) that penetrates through the punched area 313 of the substrate 31. The package apparatus 3 is suitable for products manufactured with an FBGA process.

One difference from the previous embodiment is that the conductive structure 34 is electrically connected to the substrate via the punched area 313. By means of the protrusion structure 331, a substantial gap D2 is maintained between the chip 32 and the substrate 31.

In order for the gap D2 to separate the chip 32 from the substrate 31 appropriately, the protrusion structure has an average height above the substrate 31 ranging from about, for example, 10 to 75 μm. Similarly in this embodiment, the protrusion structure 331 may be formed from, for example, either a metallic or a non-metallic material, while the adhesive layer 332 may be made of a material selected from a group including, for example, a conductive glue, a nonconductive glue, or a combination thereof. In a case of a thin chip, a conductive glue may be used as the material of the adhesive layer 332.

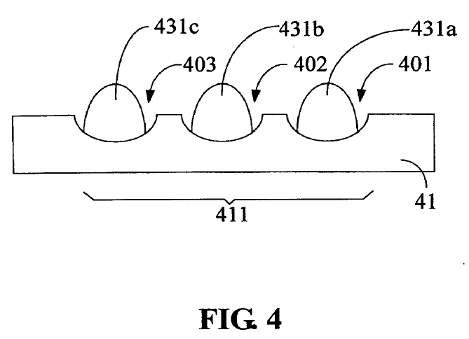

Referring now to FIG. 4, a variation of the protrusion structure and substrate includes a substrate 41 which has at least one recess 401, 402, 403 disposed in a first area 411 bonded to a chip (not shown). In this embodiment, the substrate 41 has the at least one recess 401, 402, 403 disposed in the first area 411. Only recesses 401, 402 and 403 are illustrated. A skilled artisan will recognize that any number of recesses, laid out in various patterns, may be employed. For example, from a plan view perspective (not shown) the recesses may be formed in either a one-dimensional array of rows of recesses or a two-dimensional array of recesses laid out on a Cartesian grid, radial pattern, or some other array pattern.

A protrusion structure includes a plurality of knobs 431a, 431b, 431c, although only knobs 431a, 431b, and 431c are shown formed in the recesses 401, 402, 403. Each of the knobs 431a, 431b, 431c has a height above a surface of the substrate 41 ranging from about, for example, 10 to 75 μm, (i.e., protrudes from the substrate surface to a height substantially within this range to appropriately separate the chip (not shown) bonded to the substrate 41.) Similarly, the protrusion structure may be formed from, for example, a metallic or non-metallic material.

It should be noted that the embodiment of FIG. 4 may be applied in combination with other embodiments described herein to provide a gap between the substrate and the chip to prevent the adhesive from creeping to other areas. The adhesion structure of the present invention is adapted to provide an adhesion gap or separation between the substrate and the chip to avoid deterioration of the conductivity or disruption of the conductive structures.

The present invention is described above with reference to specific embodiments thereof. It will, however, be evident to a skilled artisan that various modifications and changes can be made thereto without departing from the broader spirit and scope of the present invention as set forth in the appended claims.

For example, particular embodiments describe a number of package arrangements. A skilled artisan will recognize that these package arrangements and materials may be varied and those shown herein are for exemplary purposes only in order to illustrate the novel nature of the chip mounting concepts. Other materials, such as a semiconductive material, may be utilized to form various features described herein.

Additionally, a skilled artisan will further recognize that the techniques described herein may be applied to any type of chip mounting system whether or not a thin chip is employed. The application to a thin chip in the semiconductor industry is purely used as an exemplar to aid one of skill in the art in describing various embodiments of the present invention.

Moreover, the term semiconductor should be construed throughout the description to include data storage, flat panel display, as well as allied or other industries. These and various other embodiments are all within a scope of the present invention. The specification and drawings are, accordingly, to be regarded in an illustrative rather than a restrictive sense.

What is claimed is:

1. A packaging apparatus comprising:
a substrate having an interior area and a peripheral area, the substrate configured to have an integrated circuit chip bonded to an adhesion structure located substantially within the interior area of the substrate, the substrate being further configured to have the integrated circuit chip be electrically coupled to the peripheral area of the substrate through a conductive structure;
the adhesion structure having:
a bonding area configured to accept an adhesive layer formed between the integrated circuit chip and the interior area of the substrate; and
at least one protrusion structure being formed substantially within the bonding area of the substrate and configured to define a gap between the integrated circuit chip and the interior area of the substrate.

2. The packaging apparatus of claim 1 wherein the adhesive layer includes a material selected from a group consisting of a conductive glue, a nonconductive glue, and a combination thereof

3. The packaging apparatus of claim 1 wherein the at least one protrusion structure includes a plurality of knobs.

4. The packaging apparatus of claim 3 wherein each of the plurality of knobs has a height between about 10 micrometers and 75 micrometers.

5. The packaging apparatus of claim 1 wherein the at least one protrusion structure is formed from a metallic material.

6. The packaging apparatus of claim 1 wherein the at least one protrusion structure is formed from a non-metallic material.

7. The packaging apparatus of claim 1 wherein the interior area of the substrate has at least one concave region and the at least one protrusion structure is located within the at least one concave region.

8. The packaging apparatus of claim 1 wherein the interior area of the substrate includes a plurality of concave regions and a plurality of knobs is located within at least some of the plurality of concave regions.

9. The packaging apparatus of claim 1 wherein the at least one protrusion structure has a height between about 10 micrometers and 75 micrometers.

10. A packaging apparatus comprising:
a substrate having an interior area and a peripheral area, the interior area surrounding a punched area located substantially within a central portion of the substrate, the substrate configured to have an integrated circuit chip bonded to an adhesion structure located substantially within the interior area on a first surface of the substrate, the substrate being further configured to have the integrated circuit chip be electrically coupled to the interior area located on a second surface of the substrate through a conductive structure;
the adhesion structure having:
a bonding area configured to accept an adhesive layer formed between the integrated circuit chip and the interior area of the substrate; and
at least one protrusion structure being formed substantially within the bonding area of the substrate and configured to define a gap between the integrated circuit chip and the interior area of the substrate.

11. The packaging apparatus of claim 10 wherein the adhesive layer includes a material selected from a group consisting of a conductive glue, a nonconductive glue, and a combination thereof.

12. The packaging apparatus of claim 10 wherein the at least one protrusion structure includes a plurality of knobs.

13. The packaging apparatus of claim 12 wherein each of the plurality of knobs has a height between about 10 micrometers and 75 micrometers.

14. The packaging apparatus of claim 10 wherein the at least one protrusion structure is formed from a metallic material.

15. The packaging apparatus of claim 10 wherein the at least one protrusion structure is formed from a non-metallic material.

16. The packaging apparatus of claim 10 wherein the interior area of the substrate has at least one concave region and the at least one protrusion structure is located within the at least one concave region.

17. The packaging apparatus of claim 10 wherein the interior area of the substrate includes a plurality of concave regions and a plurality of knobs is located within at least some of the plurality of concave regions.

18. The packaging apparatus of claim 10 wherein the at least one protrusion structure has a height between about 10 micrometers and 75 micrometers.

19. The packaging apparatus of claim 10 wherein the conductive structure is configured to be routed from the first surface of the substrate to the second surface of the substrate through the punched area.

20. A method of mounting an integrated circuit chip to a packaging apparatus, the method comprising:
forming one or more adhesion structures onto an interior area on a first surface of a substrate, the one or more adhesion structures having a plurality of knobs;
placing an adhesive material substantially within the interior area of the substrate and in proximity to the plurality of knobs; and
adhering the integrated circuit chip to the substrate by placing the integrated circuit chip over the plurality of knobs and in contact with the adhesive material.

21. The method of claim 20 further comprising electrically coupling the integrated circuit chip to a peripheral area on the first surface of the substrate though a conductive structure.

22. The method of claim 20 further comprising electrically coupling the integrated circuit chip to the interior area on a second surface of the substrate though a conductive structure.

23. The method of claim 20 further comprising selecting the adhesive material to be at least partially formed a material selected from a group consisting of a conductive glue, a nonconductive glue, and a combination thereof

24. The method of claim 20 further comprising locating the plurality of knobs in a plurality of concave regions formed within the interior area.

25. The method of claim 20 further comprising forming a punched area concentrically within the interior area.
